(19) United States
(12) Patent Application Publication
(10) Pub. No.: US 2025/0370079 A1
(43) Pub. Date: Dec. 4, 2025

(54) DESKTOP EPR IMAGER AND METHOD

(71) Applicant: O2M Technologies, LLC, Chicago, IL (US)

(72) Inventors: Mrignayani Kotecha, Chicago, IL (US); Boris Meerovich Epel, Chicago, IL (US)

(21) Appl. No.: 19/224,679

(22) Filed: May 30, 2025

Related U.S. Application Data
(60) Provisional application No. 63/655,838, filed on Jun. 4, 2024.

(51) Int. Cl. G01R 33/60; G01N 24/10; G01R 33/36; G01R 33/383; G01R 33/385

(52) U.S. Cl. CPC G01R 33/60; G01N 24/10; G01R 33/3607; G01R 33/383; G01R 33/3852

(57) ABSTRACT

A small-size electron paramagnetic resonance imaging (EPRI) instrument includes an environment-controlled resonator configured to excite and detect electron spins at a resonance frequency. The instrument enables oxygen imaging of cell-seeded wells of standard 96-wells of multi-well plate manipulated by a mechanical stage. One example is configured for long multiple-well strips. In combination with an oxygen-reporting molecular, one example provides partial oxygen pressure (pO₂) maps of cells in wells that can be used for cell viability measurements and analysis of drug efficacy when used with drugs and cells.

### CROSS-REFERENCE TO RELATED APPLICATION

This application claims priority benefit, under 35 U.S.C. § 119 (e), of U.S. Provisional Patent Application No. 63/655,838 filed Jun. 4, 2024 by Mrignayani Kotecha et al., titled “Desktop EPR imager,” which is incorporated herein by reference in its entirety.

### FIELD OF THE INVENTIONS

This invention relates to the field of medical imaging, and more particularly, to three-dimensional electron paramagnetic resonance (EPR) imaging of an in vitro cell environmental parameter, such as oxygen partial pressure, pH, and/or viscosity, wherein the magnetic-field strength for EPR imaging (EPRI) can include a relatively low-strength magnetic field, such as between 6 mT and 42 mT, and wherein, in some embodiments, the EPRI uses a reporter molecule (also called spin probe or contrast agent) delivered to the place of imaging through injection, diffusion, or other transportation processes.

### BACKGROUND OF THE INVENTION

Viable cells are essential for discoveries in biology, developing efficient cell, tissue, and gene therapies, drug development, toxicity studies, and understanding the action mechanism of proteins, genes, and the microenvironment. However, current methods to assess viable cells, typically assay-based, such as MTT, PicoGreen, luciferase, or clonogenic assays, are inadequate and do not provide spatiotemporal information. They also fail when cells are seeded in biomaterials or an integral part of the extracellular matrix in an organ or a tissue.

The following documents are noted:
M. Kotecha, L. Wang, S. Hameed, N. Viswakarma, M. Ma, C. Stabler, C. Hoesli, B. Epel, In Vitro Oxygen Imaging of Acellular and Cell-loaded Beta Cell Replacement Devices Scientific Reports (2023).
B. Epel, M. Kotecha, H. J. Halpern, In vivo preclinical cancer and tissue engineering applications of absolute oxygen imaging using pulse EPR, J Magn Reson 280 (2017) 149-157.
S. Hameed, N. Viswakarma, G. Babakhanova, C. G. Simon, B. Epel, M. Kotecha, Nondestructive, Longitudinal, 3D Oxygen Imaging of Cells in a Multi-Well Plate Using Pulse Electron Paramagnetic Resonance Imaging, npj imaging 2(1) (2024) 8.
C. Buyse, L. Mignion, N. Joudiou, S. Melloul, B. Driesschaert, B. Gallez, Sensitive simultaneous measurements of oxygenation and extracellular pH by EPR using a stable monophosphonated trityl radical and lithium phthalocyanine, Free Radical Biology and Medicine 213 (2024) 11-18.
H. Xu, D. Jiao, A. Liu, K. Wu, Tumor organoids: applications in cancer modeling and potentials in precision medicine, Journal of Hematology & Oncology 15(1) (2022) 58.
B. Epel, M. K. Bowman, C. Mailer, H. J. Halpern, Absolute oxygen R1e imaging in vivo with pulse electron paramagnetic resonance, Magn Reson Med 72(2) (2014) 362-8.

There remains a need for three-dimensional EPR imaging of in vitro cell environmental parameters such as oxygen partial pressure, pH, and/or viscosity using a relatively low magnetic field.

### SUMMARY OF THE INVENTION

In some embodiments, the present invention provides an electron paramagnetic resonance imaging (EPRI) system for imaging many wells of a multiple-well cell plate, the system including: a resistive magnet driven by a power supply to generate a static magnetic field; three magnetic field gradient coils configured to provide three magnetic fields in orthogonal alignment, three coil amplifiers each of which are coupled to a magnetic field gradient coil in one-to-one relation, and an electronic circuit to drive the amplifiers; a radio frequency (RF) signal source, an RF power amplifier, and a pulse programmer configured to generate a substantially coherent polyphase sequence of RF pulses and excite a spin probe of a sample in the plate without heating the sample; a resonator configured to focus RF power on the sample; and a computer system configured to acquire and process an image, acquire, quantify and map pO2 data associated with a spin probe having oxygen-dependent T2* and/or spin-spin relaxation time and/or spin-lattice relaxation time.

In some embodiments, the present invention provides an electron paramagnetic resonance imaging (EPRI) method for imaging a plurality of wells of a multiple-well cell plate, the method including: providing a static magnetic field; generating three orthogonal magnetic-field gradients; generating a substantially coherent polyphase sequence of RF pulses to excite a spin probe of a sample in one the plurality of wells of the plate without heating the sample; focusing RF power on the sample with a resonator that obtains a signal from the sample; and acquiring the signal from the resonator and processing an image that quantifies and maps pO₂ data associated with the spin probe having oxygen-dependent T₂* and/or spin-spin relaxation time and/or spin-lattice relaxation time.

In some embodiments, the present invention is suitable for medical imaging. One configuration provides three-dimensional imaging of an in vitro cell environmental parameter. An environmental parameter can include oxygen partial pressure, pH, or viscosity. The field for electron paramagnetic resonance (EPR) can include a relatively low magnetic field, such as between 6 mT and 42 mT.

EPR imaging (EPRI) uses a reporter molecule (also called spin probe or contrast agent) delivered to the place of imaging through injection, diffusion, or other transportation processes. The spectroscopic properties, such as linewidth, signal intensity, or relaxation rates R₁, R₂, R₂* of the molecule are chosen to report the parameter of interest such as oxygen, viscosity, or pH. The EPRI technology then allows the determination of spectroscopic parameters of interest in every place of the imaged object, which is converted to the cell microenvironment parameter using pre-determined calibration.

One example includes an EPRI apparatus compatible with imaging small objects such as those carried by well plates used in biological labs. To accomplish this, in addition to EPRI components, the apparatus also is configured to maintain conditions used in biochemical oxygen demand (BOD) incubators. Some conditions include maintaining a controlled gas atmosphere (for example, 95% air+5% CO₂, or any other gas conditions), humidity, and temperature. One example is configured with a mechanical stage with one degree of freedom. The stage can allow for improved efficiency and can be configured for sample loading and sample moving through the sensing area.

Oxygen imaging can be utilized to assess cell viability. Monitoring pH along with oxygen can provide information about tumor progression. Tumor organoids can enable personalized treatments. In one example, a desktop EPRI instrument can enable such measurements in a fast and efficient way. The desktop instrument can be configured for use on a benchtop.

One example includes a small resonator size and a mechanical stage capable of moving the sample. The compact size of the instrument and stage allows rapid EPRI experiments. An example is configured for measuring 8 and 24 wells and enables a method to image oxygen or other parameters of interest in the long multiple-well strips in a small size instrument.

Each of these non-limiting examples can stand on its own, or can be combined in various permutations or combinations with one or more of the other examples.

This overview is intended to provide an overview of the subject matter of the present patent application. It is not intended to provide an exclusive or exhaustive explanation of the invention. A detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 includes a system schematic illustrating an electron paramagnetic resonance imaging (EPRI) system that operates to quantify pO₂ (or pH, etc.) information associated with a cell culture growing in the well of an 8-well plate.

FIG. 2 includes an illustration of an embodiment of a fixed resonator and a stage configured to move an 8-well cell culture plate along the resonator. The left-most portion shows a view of a unit, and the right-most portion shows an exploded view of the unit.

FIG. 3 includes an illustration of an embodiment of a fixed resonator and a stage configured to move a 24-well cell culture plate assembled of 8-well cell culture plates above the resonator. The left-most portion shows a view of a unit, and the right-most portion shows an exploded view of the unit.

### DETAILED DESCRIPTION OF THE INVENTION

An example of the present subject matter provides electron paramagnetic resonance oxygen imaging. Briefly, the reporter molecule is paramagnetic. A paramagnetic compound is characterized by the presence of internal magnetic moment, electron spins. A constant magnetic field is applied to the reporter molecule. Magnetic field splits energy levels of spins by magnetic field-dependent quantity (Zeeman effect). Then, an alternating magnetic field is applied with a frequency equal to the energy of the splitting divided by the Planck constant (also known as resonance frequency). This field induces a transition between energy levels of the spins, resulting in the appearance of global magnetization orthogonal to the direction of the main magnetic field detected macroscopically as an EPR signal.

One example of the present subject matter is operated in pulse mode and applies an alternating field in the form of short pulses with a duration significantly shorter than the relaxation times of the sample. This can be referred to as Pulse EPR.

In addition to the constant magnetic field, the gradients of the magnetic field are created. The typical configuration of the gradient results in a magnetic field linearly changing along a line passing the center of coordinates, with no changes at the center of coordinates (gradient isocenter). Three gradient coils with the directions along the principal axis of the system (X, Y, and Z) can be applied. The combination of the gradients allows the arbitrary direction of the gradient. The EPR spectrum collected when the gradient is applied is called a projection and additionally, to zero gradient spectrum carries spatial information about the object. The set of projections collected along different gradient directions can be converted into a three-dimensional image of the object.

In one example, an oxygen-sensitive EPR spin probe is introduced to the system. The EPR signals acquired after a series of radio frequency (RF) pulses decay over time. A part of this decay is due to interaction between the oxygen molecules and the electron spins. Three relaxation times can be considered in analysis of the decay. Spin-lattice relaxation time (sometimes denoted T₁) refers to the decay due to the loss of energy by the spin system to the surroundings. Spin-spin relaxation time (sometimes denoted as T₂) refers to the decay of the global magnetization due to reorientation of spins (that is, loss of common orientation, no energy loss). T₂* (also referred to as T₂ star) time refers to the decay of signal due to all factors, including the interaction of electron spins with any magnetic particles such as paramagnetic nuclei, other spins etc.

For some spin probes suitable for oximetry, the inverse of all the above relaxation times (relaxation rates) are linearly dependent on oxygen concentrations (slowest relaxation rates for low oxygen concentrations). The spin-lattice relaxation rate has the least dependence on other than oxygen concentration factors and thus provides a good measurement of oxygen.

Spin probe relaxation rates can be measured by applying particular sequences of RF pulses, designed to highlight only a particular mechanism of relaxation. Combining spin-lattice measurement pulse sequences with the imaging methodology allows measurement of three-dimensional maps of oxygen concentrations.

### EXAMPLES

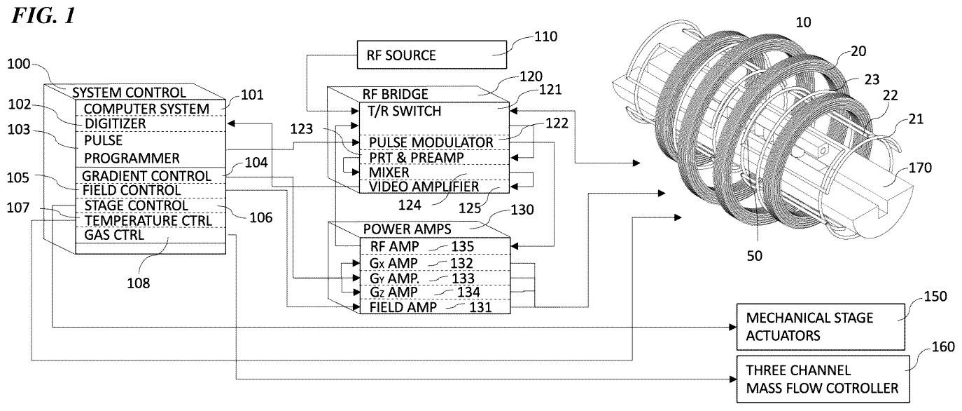

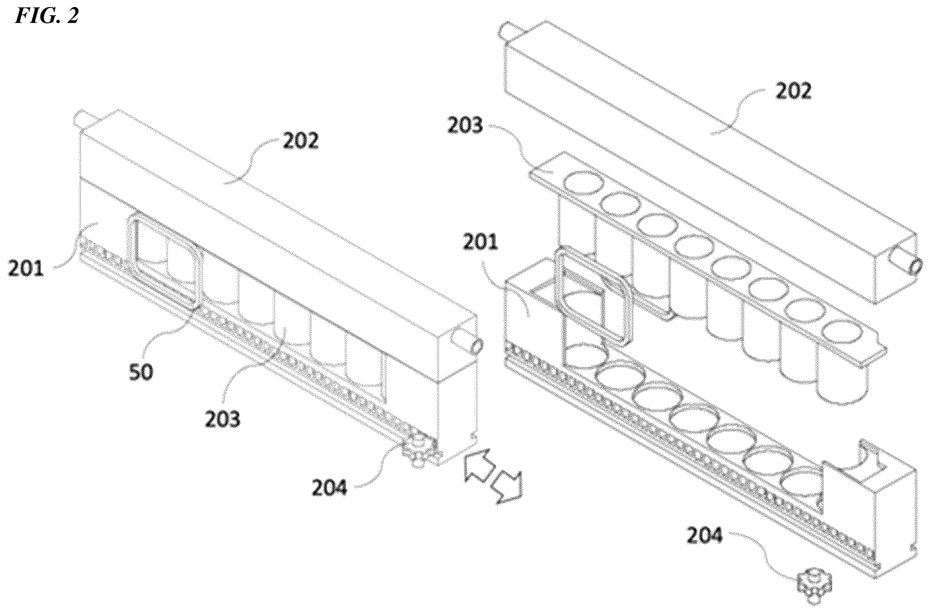

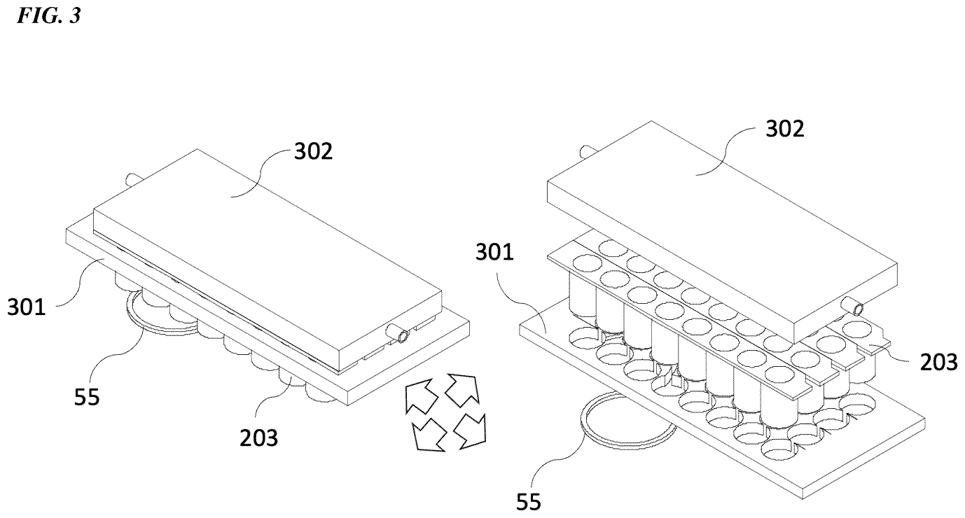

FIG. 1 is a simplified system diagram illustrating an electron paramagnetic resonance imaging (EPRI) system that operates to quantify pO₂ information in a cell culture growing in the multiple-well plates. EPRI system 1 comprises an EPR magnet assembly 10, system control 100, RF source 110, RF bridge 120, and power amplifiers 130. In addition, the example here includes mechanical stage actuators 150 and mass flow gas controllers 160. A base platform 170 serves as a support for resonators and mechanical stages described in FIG. 2 and FIG. 3. The units shown here can be housed together in one unit or can be provided in various combinations.

EPR magnet assembly 10 includes a 4-coil main magnet 20, three orthogonal gradients coils Gx 21, Gy 22, and Gz 23 and Helmholtz resonator 50. The magnet coils are connected to power amplifier unit 130 comprised of the main magnetic field amplifier 131, and gradient amplifiers 132, 133, and 134.

The RF bridge 120 receives the basic frequency from RF source 110. The pulse modulator 122 of the bridge uses a combination of RF switches and phase shifters activated by the pulse sequence produced by pulse programmer 104 to generate the pulse sequence. The pulse sequence is fed to power amplifier 135 and then fed into RF bridge 121, which directs excitation power to the reflection type resonator 50 and then routes the detected signals to the preamplifier 123. Preamplifier 123 can include protection circuitry to prevent damage from high power. The detected signals are down-converted using mixer 124 and LO signal from source 110, amplified by video amplifier 125, and then digitized by digitizer 102.

Control 100 includes a computer system 101 with hardware controllers including signal digitizer 102, pulse programmer 103, gradient 104 and field 105 controllers, controller of mechanical stage 106 coupled to stage 150, temperature controller 107, and gas controller interface 108 coupled to controller 160 configured to provide an arbitrary mixture of three gasses including N2, O2 and CO2 and equipped with a gas humidifier. Computer system 101 can be configured to execute image acquisition software, image reconstruction software, software for image processing, and visualization software.

FIG. 2 includes an illustration of an embodiment of resonator 51 fixed within the magnet system 10 and the stage that moves 8-well cell culture plate 203 along the resonator. Plate 203 is held by holder 201 and air circulating cover 202 clamped together. The RF resonator 50, including two coils in Helmholtz orientation, allows an unobstructed movement of the holder 201, plate 203 and cover 202 assembly as shown in the figure. This movement can be facilitated by the gear 204 and the corresponding director in magnet base assembly 51.

FIG. 3 includes an illustration of an embodiment of a fixed resonator and the stage that moves four 8-well cell culture plates 203 assembled into a 24-well cell culture plate above the resonator. The RF resonator 55 includes a single coil parallel to the bottom of the plates 203 and allows an unobstructed movement of the holder 301, plates 203, and cover 302 assembly in the plane parallel to the resonator 55 plane as shown in the figure.

### Methods

Oxygen Imaging: Cells or cell cultures do not have a detectable level of electron spins. Before oxygen measurements, a non-toxic water-soluble spin probe, such as OXO63 or OXO71, is added to the media. In one example, a small volume of highly concentrated probe solution is added to achieve the desired concentration (1 mM and below) inside each well.

An 8-well strip plate, or similar cell holding structure, is then installed into the locking mechanism of the digitally controlled stage of the device extended outside the apparatus and covered with circulating gas attachment for providing a desired atmosphere and humidity to the cell culture. The stage then conveys the well plate into the instrument, positioning the well plate inside the EPR resonator. The heating system circulates air around the structure to achieve the desired temperature. Then, the oxygen measurements are performed.

The length of the well strip line exceeds the length of the resonator, only a portion of strip line wells are measured at a time. After that, the stage automatically moves the strip line to position the next group of wells into the resonator. This procedure is repeated until signal is measured in each well of the plate.

### Various Notes

The above description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

Although the following detailed description contains many specifics for the purpose of illustration, a person of ordinary skill in the art will appreciate that many variations and alterations to the following details are within the scope of the invention. Specific examples are used to illustrate particular embodiments; however, the invention described in the claims is not intended to be limited to only these examples, but rather includes the full scope of the attached claims. Accordingly, the following preferred embodiments of the invention are set forth without any loss of generality to, and without imposing limitations upon the claimed invention. Further, in the following detailed description of the preferred embodiments, reference is made to the accompanying drawings that form a part hereof, and in which are shown by way of illustration specific embodiments in which the invention may be practiced. It is understood that other embodiments may be utilized and structural changes may be made without departing from the scope of the present invention.

It is specifically contemplated that the present invention includes embodiments having combinations and subcombinations of the various embodiments and features that are individually described herein (i.e., rather than listing every combinatorial of the elements, this specification includes descriptions of representative embodiments and contemplates embodiments that include some of the features from one embodiment combined with some of the features of another embodiment, including embodiments that include some of the features from one embodiment combined with some of the features of embodiments described in the patents and application publications incorporated by reference in the present application). Further, some embodiments include fewer than all the components described as part of any one of the embodiments described herein.

In some embodiments, the present invention provides an electron paramagnetic resonance imaging (EPRI) system for imaging many wells of a multiple-well cell plate, the system including: a resistive magnet driven by a power supply to generate a static magnetic field; three magnetic field gradient coils configured to provide three magnetic fields in orthogonal alignment, three coil amplifiers each of which are coupled to a magnetic field gradient coil in one-to-one relation, and an electronic circuit to drive the amplifiers; a radio frequency (RF) signal source, an RF power amplifier, and a pulse programmer configured to generate a substantially coherent polyphase sequence of RF pulses and excite a spin probe of a sample in the plate without heating the sample; a resonator configured to focus RF power on the sample; and a computer system configured to acquire and process an image, acquire, quantify and map pO2 data associated with a spin probe having oxygen-dependent T2* and/or spin-spin relaxation time and/or spin-lattice relaxation time.

Some embodiments further include a permanent magnet (rather than a resistive magnet) and an offset coil configured for fine magnetic field adjustment.

Some embodiments further include a Halbach magnet array (rather than a resistive magnet) and an offset coil configured for fine magnetic field adjustment.

In some embodiments, the system is configured for a magnetic field strength from about OT to about 50 mT. In some embodiments, the system is configured for a magnetic field strength from about 1 mT to about 50 mT. In some embodiments, the system is configured for a magnetic field strength from about 4 mT to about 45 mT. In some embodiments, the system is configured for a magnetic field strength from about 10 mT to about 40 mT.

Some embodiments further include an RF sequence having a frequency from about 0 Hz to about 1.5 GHz.

In some embodiments, the magnet has a footprint less than 0.25 m² and has a weight less than 50 kg.

In some embodiments, the sample is carried in an environment-controlled apparatus with wells of a multiple-well cell plate.

In some embodiments, the multiple-well cell plate includes an air circulating cover.

Some embodiments further include a mixture of gasses circulated above wells of the multiple-well cell plate.

Some embodiments further include a temperature controller coupled to the multiple-well cell plate, the temperature controller configured to circulate tempered air.

In some embodiments, the temperature controller is configured to maintain a temperature between 35° C. and 40° C. for a specified incubation time for cells in the plate.

Some embodiments further include a single-axis, front-to-back mechanical stage configured to carry the multiple-well cell plate and configured to selectively position the wells of the multiple-well cell plate relative to the resonator.

In some embodiments, the resonator is configured to receive signals from a portion of the multiple-well cell plate and configured to allow selective positioning of the plate to align a selected well of the plate.

In some embodiments, the system is configured to generate an image of all wells of the multiple-well cell plate by sequential imaging of parts of the multiple-well cell plate and then combining them together to form a final image.

In some embodiments, the mechanical stage is configured to position the plate clear of the resonator.

In some embodiments, the mechanical stage is configured for front-to-back unobstructed motion of the multiple-well cell plate.

In some embodiments, the system is configured to focus RF power on a portion of the sample using resonator located under the sample.

Some embodiments further include a two-axis, front-to-back and left-to-right mechanical stage, wherein the stage includes a holder for multiple rows of multiple-well strips and is configured for positioning the sample relative to the resonator.

In some embodiments, the system is configured to generate an image of all wells of the multiple-well cell plate by sequential imaging by relocating the mechanical stage in front-to-back and left-to-right direction of parts of the multiple-well cell plate and then combining them together to form a final image.

In some embodiments, the present invention provides an electron paramagnetic resonance imaging (EPRI) method for imaging a plurality of wells of a multiple-well cell plate, the method including: providing a static magnetic field; generating three orthogonal magnetic-field gradients; generating a substantially coherent polyphase sequence of RF pulses to excite a spin probe of a sample in one the plurality of wells of the plate without heating the sample; focusing RF power on the sample with a resonator that obtains a signal from the sample; and acquiring the signal from the resonator and processing an image that quantifies and maps pO₂ data associated with the spin probe having oxygen-dependent T₂* and/or spin-spin relaxation time and/or spin-lattice relaxation time.

In some embodiments of the method, the multiple-well cell plate includes wells arranged in a two-dimensional pattern of wells, and the method further includes successively positioning each well of the two-dimensional pattern of wells over the resonator to provide images of each of the plurality of wells by relocating the multiple-well cell plate and then combining the images together to form a combined image.

The leading digit(s) of reference numbers appearing in the Figures generally corresponds to the Figure number in which that component is first introduced, such that the same reference number is used throughout to refer to an identical component which appears in multiple Figures Signals and connections may be referred to by the same reference number or label, and the actual meaning will be clear from its use in the context of the description.

It is to be understood that the above description is intended to be illustrative, and not restrictive. Although numerous characteristics and advantages of various embodiments as described herein have been set forth in the foregoing description, together with details of the structure and function of various embodiments, many other embodiments and changes to details will be apparent to those of skill in the art upon reviewing the above description. The scope of the invention should be, therefore, determined with reference to the appended claims, along with the full scope of equivalents to which such claims are entitled. In the appended claims, the terms “including” and “in which” are used as the plain-English equivalents of the respective terms “comprising” and “wherein,” respectively. Moreover, the terms “first,” “second,” and “third,” etc., are used merely as labels, and are not intended to impose numerical requirements on their objects.

1. An electron paramagnetic resonance imaging (EPRI) system for imaging a plurality of wells of a multiple-well cell plate, the system comprising:
a magnet that provides a static magnetic field;
three magnetic-field-gradient coils configured to provide three magnetic fields in orthogonal alignment to one another;
three coil amplifiers, each of which is coupled to a respective one of the three magnetic-field-gradient coil, and an electronic circuit operatively coupled to drive the three coil amplifiers;
a radio frequency (RF) signal source, an RF power amplifier, and a pulse programmer configured to generate a substantially coherent polyphase sequence of RF pulses to excite a spin probe of a sample in one the plurality of wells of the plate without heating the sample;
a resonator configured to focus RF power on the sample; and
a computer system configured to acquire and process an image, acquire, quantify and map pO₂ data associated with a spin probe having oxygen-dependent T₂* and/or spin-spin relaxation time and/or spin-lattice relaxation time.

2. The system of claim 1, wherein the magnet that provides the static magnetic field includes:
a permanent magnet, and
an offset coil operatively coupled to provide fine magnetic-field adjustment.

3. The system of claim 1, wherein the magnet that provides the static magnetic field includes: a Halbach magnet array, and
an offset coil configured for fine magnetic field adjustment.

4. The system of claim 1, wherein the magnet that provides the static magnetic field includes an electromagnet driven by a power supply to generate the static magnetic field, and is configured for a magnetic field strength from about 1 mT to about 50 mT.

5. The system of claim 1, wherein the magnet has a footprint less than 0.25 m² and a weight of less than 50 kg.

6. The system of claim 1, wherein the sample is carried in an environmentally controlled apparatus holding the wells of the multiple-well cell plate.

7. The system of claim 6, wherein the multiple-well cell plate includes an air-circulating cover.

8. The system of claim 7, further including a gas circulator configured to circulate a mixture of gasses above wells of the multiple-well cell plate.

9. The system of claim 6, further including a temperature controller coupled to the multiple-well cell plate, the temperature controller configured to circulate tempered air.

10. The system of claim 9, wherein the temperature controller is configured to maintain a temperature between 35° C. and 40° C. for a specified incubation time for cell samples in wells of the plate.

11. The system of claim 1, further including a single-axis, front-to-back mechanical stage configured to carry the multiple-well cell plate and configured to selectively position the wells of the multiple-well cell plate relative to the resonator.

12. The system of claim 1, wherein the resonator is configured to receive signals from a portion of the multiple-well cell plate and configured to allow selective positioning of the plate to align a selected well of the plate.

13. The system of claim 1, further configured to generate an image of all wells of the multiple-well cell plate by sequential imaging of parts of the multiple-well cell plate and then combining them together to form a final image.

14. The system of claim 11, wherein the mechanical stage is configured to position the plate clear of the resonator.

15. The system of claim 11, wherein the mechanical stage is configured for front-to-back unobstructed motion of the multiple-well cell plate.

16. The system of claim 1, configured to focus RF power on a portion of the sample using resonator located under the sample.

17. The system of claim 16, further including a two-axis, front-to-back and left-to-right mechanical stage, wherein the stage includes a holder for multiple rows of multiple-well strips and is configured for positioning each sample relative to the resonator.

18. The system of claim 17 further configured to generate an image of all wells of the multiple-well cell plate by sequential imaging by relocating the mechanical stage in front-to-back and left-to-right direction of parts of the multiple-well cell plate and then combining them together to form a final image.

19. An electron paramagnetic resonance imaging (EPRI) method for imaging a plurality of wells of a multiple-well cell plate, the method comprising:
providing a static magnetic field;
generating three orthogonal magnetic-field gradients;
generating a substantially coherent polyphase sequence of RF pulses to excite a spin probe of a sample in one the plurality of wells of the plate without heating the sample;
focusing RF power on the sample with a resonator that obtains a signal from the sample; and
acquiring the signal from the resonator and processing an image that quantifies and maps pO₂ data associated with the spin probe having oxygen-dependent T₂* and/or spin-spin relaxation time and/or spin-lattice relaxation time.

20. The method of claim 19, wherein the multiple-well cell plate includes wells arranged in a two-dimensional pattern of wells, the method further including
successively positioning each well of the two-dimensional pattern of wells over the resonator to provide images of each of the plurality of wells by relocating the multiple-well cell plate and then combining the images together to form a combined image.
